(19) United States
(12) Patent Application Publication
(10) Pub. No.: US 2024/0413172 A1
(43) Pub. Date: Dec. 12, 2024

(54) DISPLAY PANEL AND DISPLAY DEVICE

(71) Applicant: HKC CORPORATION LIMITED, Shenzhen (CN)

(72) Inventors: Rong ZHANG, Shenzhen (CN); Lidan YE, Shenzhen (CN)

(21) Appl. No.: 18/626,651

(22) Filed: Apr. 4, 2024

(30) Foreign Application Priority Data
Jun. 7, 2023 (CN) 202310665149.0

(51) Int. Cl. H01L 27/12; H01L 25/075; H01L 25/16; H01L 33/62

(52) U.S. Cl. CPC H01L 27/1244; H01L 25/0753; H01L 25/167; H01L 33/62

(57) ABSTRACT

A display panel and a display device are provided in the disclosure. The display panel includes a display region, a fan-out region, and a binding region. The fan-out region and the binding region are stacked on the display region. The binding region is co-planar with the fan-out region. The display region includes a substrate, a functional structure layer, and a first insulation layer stacked sequentially. The fan-out region and the binding region are stacked on the first insulation layer. The functional structure layer includes multiple functional lines. The fan-out region includes multiple electrical connection lines. The binding region includes multiple pin terminals. The multiple electrical connection lines electrically connect the multiple functional lines to the multiple pin terminals in one-to-one correspondence.

### CROSS-REFERENCE TO RELATED APPLICATION(S)

This application claims priority under 35 U.S.C. § 119 (a) to Chinese Patent Application No. 202310665149.0, filed Jun. 7, 2023, the entire disclosure of which is incorporated herein by reference.

### TECHNICAL FIELD

The disclosure relates to the field of display technology, and particularly, to a display panel and a display device.

### BACKGROUND

Narrow-bezel display panels have become one of the development trends of high-end display panels due to their advantages such as simplicity, aesthetic appearance, and high screen-to-body ratio. Especially in the design of a display screen of a mobile phone, a narrow bezel design at a source side has always been a focus point of research and product development in the industry. A bezel-less design at the source side of the display panel will significantly improve the screen-to-body ratio of the display panel, thereby improving visual and operational experience, and enhancing the aesthetics of the product.

In a traditional display panel, a fan-out wiring and a bonding lead are arranged at a source side. Because the fan-out wiring and the bonding lead have a wiring height, the fan-out wiring and the bonding lead occupy a large bezel space at the source side. This causes a wide bezel of the display panel at the source side, thereby lowing the screen-to-body ratio of the display panel, and making it difficult to meet requirements of bezel-less products.

### SUMMARY

According to a first aspect, a display panel is provided in the disclosure. The display panel includes a display region, a fan-out region, and a binding region. The fan-out region and the binding region are stacked on the display region. The binding region is co-planar with the fan-out region. The display region includes a substrate, a functional structure layer, and a first insulation layer stacked sequentially. The fan-out region and the binding region are stacked on the first insulation layer. The functional structure layer includes multiple functional lines. The fan-out region includes multiple electrical connection lines. The binding region includes multiple pin terminals. The multiple electrical connection lines electrically connect the multiple functional lines to the multiple pin terminals in one-to-one correspondence.

In a second aspect, a display device is provided. The display device includes a housing and the display panel of any one of the above implementations.

### BRIEF DESCRIPTION OF THE DRAWINGS

FIG. 1 is a schematic structural diagram of a display panel according to an implementation of the disclosure.

FIG. 2 is a cross-sectional diagram of the display panel in FIG. 1, taken along line A-A.

FIG. 3 is a schematic diagram illustrating part of wirings of the display panel in FIG. 1.

FIG. 4 is a schematic diagram illustrating another part of wirings of the display panel in FIG. 1.

FIG. 5 is a schematic diagram illustrating a drive circuit of the display panel in FIG. 1.

FIG. 6 is a schematic structural diagram of the display panel in FIG. 1 according to an implementation of the disclosure.

FIG. 7 is a schematic diagram illustrating part of wirings of the display panel in FIG. 6.

FIG. 8 is a cross-sectional diagram of the display panel in FIG. 7, taken along line B-B.

FIG. 9 is a schematic diagram illustrating a drive circuit of the display panel in FIG. 6.

FIG. 10 is a partial diagram of stacking structures of the display panel in FIG. 9 at position C.

FIG. 11 is a first partial structural diagram of the driver circuit in FIG. 9 at location C.

FIG. 12 is a second partial structural diagram of the driver circuit in FIG. 9 at location C.

FIG. 13 is a third partial structural diagram of the driver circuit in FIG. 9 at location C.

FIG. 14 is a fourth partial structural diagram of the driver circuit in FIG. 9 at location C.

FIG. 15 is a fifth partial structural diagram of the driver circuit in FIG. 9 at location C.

FIG. 16 is a sixth partial structural diagram of the driver circuit in FIG. 9 at location C.

### REFERENCE NUMERALS

1: display panel; 10: display region; 101: substrate; 102: functional structure layer; 1021: first metal layer; 1022: second insulation layer; 1023: second metal layer; 1024: third insulation layer; 103: first insulation layer; 104a: first side edge; 104b: third side edge; 105a: second side edge; 105b: fourth side edge; 11: gate line; 111: first through hole; 1111: first conductive block; 12: data line; 13: first power line; 14: second power supply line; 15: light-emitting element; 151: second through hole; 1511: second conductive block; 16: first power supply; 17: second power supply; 18: gate; 181: third through hole; 1811: third conductive block; 19: transistor; 20: fan-out region; 21: first electrical connection line; 211: first electrical connection segment; 212: second electrical connection segment; 22: second electrical connection line; 23: third electrical connection line; 24: fourth electrical connection line; 30: binding region; 31: first pin terminal; 32: second pin terminal; 33: third pin terminal; 34: fourth pin terminal.

### DETAILED DESCRIPTION

The following implementations of the disclosure will be described below with reference to the drawings in the implementations of the disclosure.

In the implementations of the disclosure, it is appreciated that term “connect” should be understood in a broad sense unless otherwise specified and limited. For example, term “connect” may refer to fixedly connect, detachably connect, or integrally connect. The term “connect” may also refer to mechanically connect, electrically connect, or communicate with each other. The term “connect” may also refer to directly connect, indirectly connect through an intermediate medium, intercommunicate interiors of two elements, or interact between two elements. For those of ordinary skill in the art, the specific meanings of the above terms in the implementations of the disclosure can be understood according to specific situations. Directional terms such as “width”, “thickness”, “up”, “down”, “inside”, and the like referred to herein which are only for directions with reference to the accompanying drawings. Therefore, the directional terms used herein are intended to better and more clearly illustrate and understand the disclosure, rather than explicitly or implicitly indicate that devices or components referred to herein must have a certain direction or be configured or operated in a certain direction and therefore cannot be understood as limitation on the disclosure. In addition, terms “first” and “second” are merely used for descriptive purposes, and should not be understood as indicating or implying relative importance or implicitly indicating the number of technical features indicated. Therefore, the feature defined with the term “first” or “second” may explicitly or implicitly include one or more of the features. In the implementations of the disclosure, the terms “a plurality of” and “multiple” mean that that the number is two or more, unless otherwise clearly specified.

In the implementations of the disclosure, the mathematical concepts mentioned, such as “parallel” and “perpendicular”, are intended to be understood in the context of the current state of the art in the field. The mathematical concepts are not meant to be interpreted as strictly absolute mathematical definitions, and some degree of variation is permissible. Approximations to “parallel” or “perpendicular” are acceptable. For example, “A is parallel to B” means that A is exactly or approximately parallel to B, with an acceptable angle between A and B that falls within a range of 0 degrees to 10 degrees. Similarly, “A is perpendicular to B” means that A is exactly or approximately perpendicular to B, with an acceptable angle between A and B that falls within a range of 80 degrees to 100 degrees.

In the implementations of the disclosure, “A is co-planar with B” means that A and B are formed simultaneously by the same patterning process.

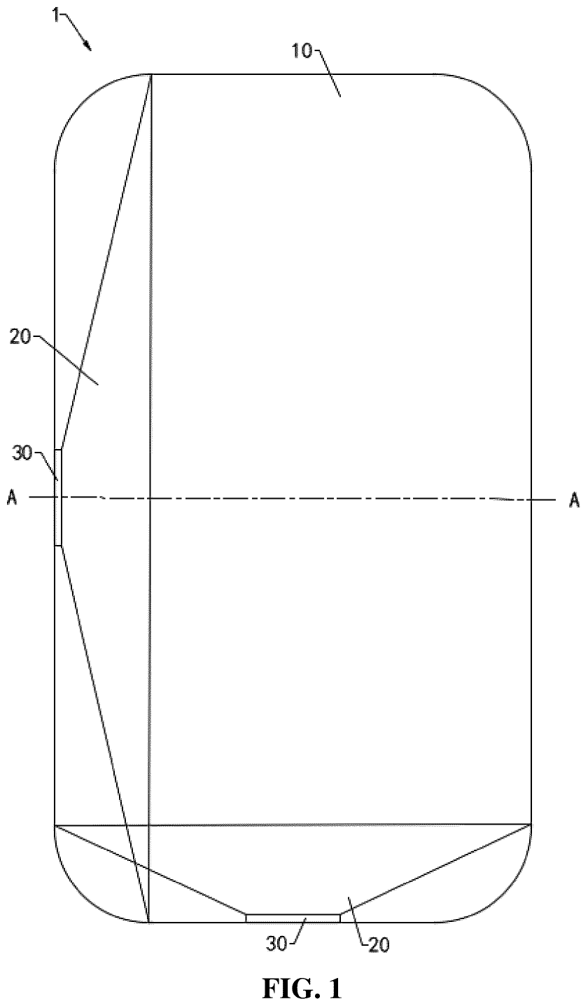

FIG. 1 is a schematic structural diagram of a display panel 1 according to an implementation of the disclosure.

As illustrated in FIG. 1, the display panel 1 provided in implementations of the disclosure is applied to a display device that has no bezel. The display device may include a housing and the display panel 1. The housing is integrated with the display panel 1. The display device may be a smart phone, a tablet computer, a game device, an augmented reality (AR) device, a notebook, a desktop computing device, a wearable device, and the like. For ease of understanding, an example that the display device is a mobile phone is taken for illustration hereinafter.

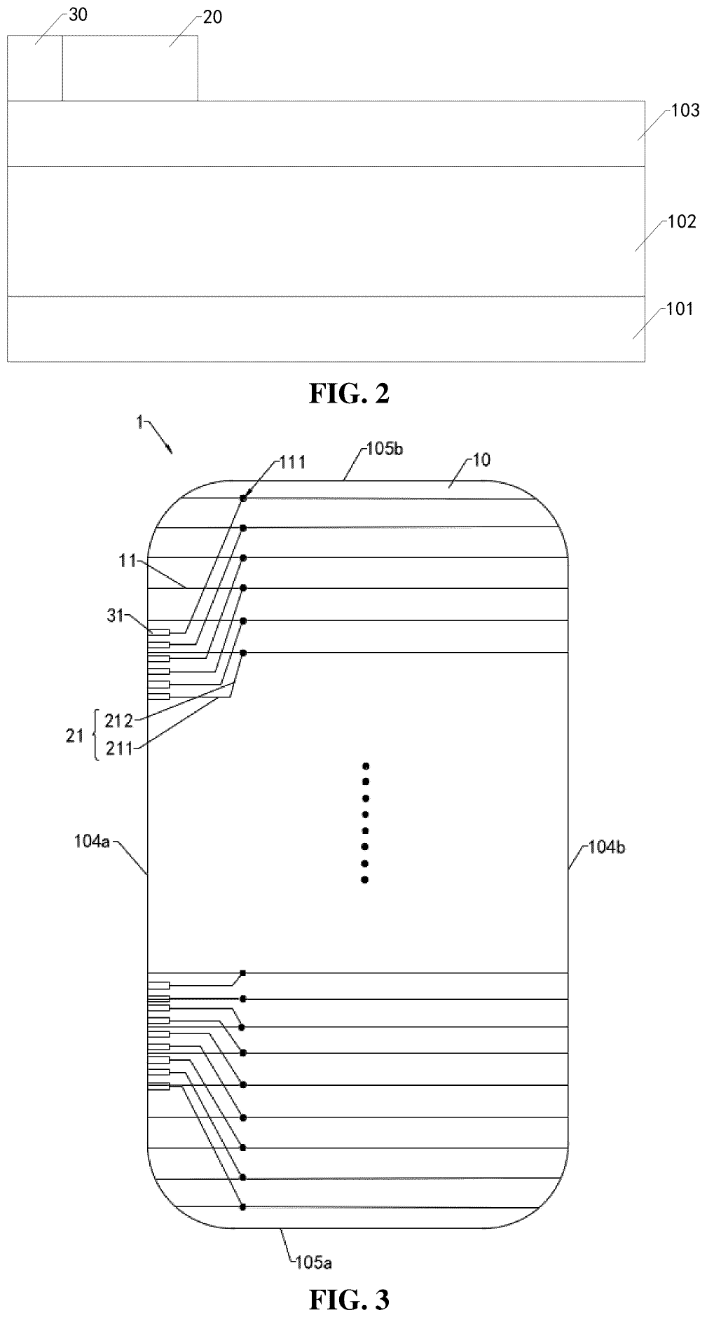

FIG. 2 is a cross-sectional diagram of the display panel 1 in FIG. 1, taken along line A-A.

As illustrated in FIGS. 1 and 2, the display panel 1 includes a display region 10, a fan-out region 20, and a binding region 30. The fan-out region 20 is stacked on the display region 10 and the binding region 30 is stacked on the display region 10. The binding region 30 is co-planar with the fan-out region 20. The display region 10 includes a substrate 101, a functional structure layer 102, and a first insulation layer 103 stacked sequentially. The fan-out region 20 and the binding region 30 are stacked on the first insulation layer 103.

Exemplarily, the functional structure layer 102 and the first insulation layer 103 are sequentially stacked at a film side of the substrate 101. The fan-out region 20 and the binding region 30 are stacked on the first insulation layer 103, thus both the fan-out region 20 and the binding region 30 may be positioned at the film side of the substrate 101 and at a side of the functional structure layer 102 away from the substrate 101.

Exemplarily, the substrate 101 may be bare glass. In other implementations, the substrate 101 may be other transparent substrates such as quartz.

In the implementations of the disclosure, both the fan-out region 20 and the binding region 30 of the display panel 1 are stacked on the display region 10, so that the display panel 1 does not have a non-display region. This allows the display panel 1 to be fully bezel-less (i.e., have no bezel) at a source side and a gate side, thereby significantly improving a screen-to-body ratio of the display panel 1, improving visual and operational experience, and enhancing the aesthetics of the product.

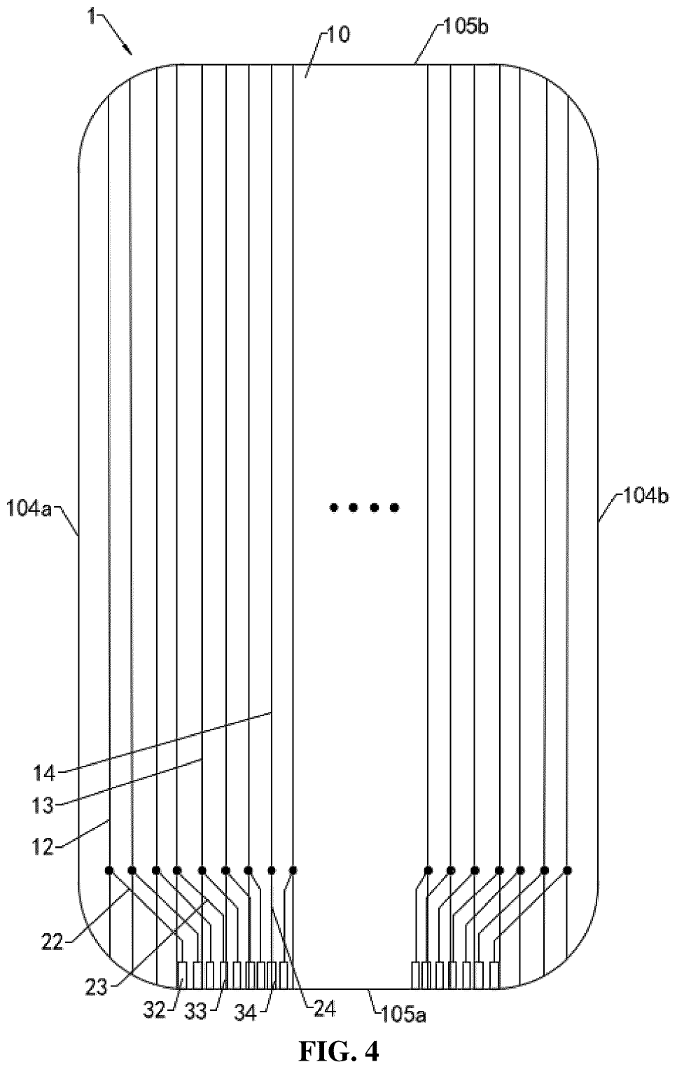

FIG. 3 is a schematic diagram illustrating part of wirings of the display panel 1 in FIG. 1. FIG. 4 is a schematic diagram illustrating another part of wirings of the display panel 1 in FIG. 1.

As illustrated in FIGS. 3 and 4, the functional structure layer 102 includes multiple functional lines. The fan-out region 20 includes multiple electrical connection lines. The binding region 30 includes multiple pin terminals. The multiple electrical connection lines electrically connect the multiple functional lines to the multiple pin terminals in one-to-one correspondence.

Exemplarily, the functional lines include multiple gate lines 11 (i.e., gate lines), multiple data lines 12 (i.e., data lines), multiple first power lines 13, and multiple second power lines 14. The electrical connection lines include first electrical connection lines 21, second electrical connection lines 22, third electrical connection lines 23, and fourth electrical connection lines 24. The multiple pin terminals include first pin terminals 31, second pin terminals 32, third pin terminals 33, and fourth pin terminals 34.

Exemplarily, each of the first electrical connection lines 21 electrically connects one of the multiple gate lines 11 to one of the first pin terminals 31. Each of the second electrical connection lines 22 electrically connects one of the multiple data lines 12 to one of the second pin terminals 32. Each of the third electrical connection lines 23 electrically connects one of the multiple first power lines 13 to one of the third pin terminals 33. Each of the fourth electrical connection lines 24 electrically connects one of the multiple second power lines 14 to one of the fourth pin terminals 34.

Exemplarily, the electrical connection line is co-planar with the pin terminal. This configuration eliminates the necessity of bending of the electrical connection line in a thickness direction of the display panel 1 during bonding of the electrical connection line to the pin terminal. As a result, it can reduce stress on the electrical connection line, where the electrical connection line is susceptible to damage under such stress, and the connection between the electrical connection line and the pin terminal is less susceptible to loosening.

In addition, the electrical connection line and the pin terminal are both manufactured by using an additional signal metal layer, which helps prevent the electrical connection line and the pin terminal from being in signal short circuit with the gate line 11, the data line 12, the first power line 13, and the second power line 14.

In addition, the electrical connection line is formed by an additional single metal layer, which helps prevent compression of a space of pixel units by the electrical connection line, thereby facilitating achievement of high resolution of the display panel 1.

As illustrated in FIGS. 3 and 4, the display region 10 includes a first side edge 104a, a third side edge 104b opposite the first side edge 104a, a second side edge 105a, and a fourth side edge 105b opposite the second side edge 105a. The first side edge 104a and the third side edge 104b are connected between the second side edge 105a and the fourth side edge 105b.

Exemplarily, the first pin terminals 31 and the first electrical connection lines 21 are closer to the first side edge 104a than the third side edge 104b.

Exemplarily, the first pin terminals 31 may be connected to the first side edge 104a.

Exemplarily, the second pin terminals 32, the third pin terminals 33, the fourth pin terminals 34, the second electrical connection lines 22, the third electrical connection lines 23, and the fourth electrical connection lines 24 are closer to the second side edge 105a.

Exemplarily, the second pin terminal 32, the third pin terminal 33, and the fourth pin terminal 34 may be connected to the second side edge 105a.

It should be understood that, part of the fan-out region 20 and part of the binding region 30 of the display panel 1 provided in the implementations of the disclosure may be arranged close to the first side edge 104a of the display region 10, and another part of the fan-out region 20 and another part of the binding region 30 of the display panel 1 may be arranged close to the second side edge 105a of the display region 10.

In the implementations of the disclosure, the first electrical connection line 21 connected to the gate line 11 is disposed close to the first side edge 104a of the display region 10. The first electrical connection line 21 may extend towards the first side edge 104a of the display panel 1 to the first pin terminal 31. The second electrical connection line 22 connected to the data line 12, the third electrical connection line 23 connected to the first power line 13, and the fourth electrical connection line 24 connected to the second power line 14 are arranged close to the second side edge 105a of the display region 10. The second electrical connection line 22 extends towards the second side edge 105a of the display panel 1 to the second pin terminal 32, the third electrical connection line 23 extends towards the second side edge 105a of the display panel 1 to the third pin terminal 33, and the fourth electrical connection line 24 extends towards the second side edge 105a of the display panel 1 to the fourth pin terminal 34. In this way, the first electrical connection line 21 can be arranged at a side different from a side at which the second electrical connection line 22, the third electrical connection line 23, and the fourth electrical connection line 24 are arranged. Such wiring arrangement can avoid too dense arrangement of the first electrical connection line 21, the second electrical connection line 22, the third electrical connection line 23, and the fourth electrical connection line 24, thereby avoiding the arrangement disorder of the electrical connection lines and the occurrence of partial overheat of the display panel 1.

Exemplarily, the first power line 13 is spaced apart from the second power line 14. The multiple data lines 12 are arranged among the first power lines 13 and the second power lines 14. Specifically, the data lines 12, the first power lines 13, and the second power lines 14 may be arranged as follows. Three data lines 12 and one first power line 13 are arranged at intervals in sequence, another set of three data lines 12 and one second power line 14 are arranged at intervals in sequence, and this arrangement is repeated.

In this way, the multiple first power supply lines 13 and the multiple second power supply lines 14 can be evenly distributed among the multiple data lines 12. This ensures that driving voltages of various regions of the display panel 1 are consistent, thereby avoiding uneven display of the display panel 1.

As illustrated in FIG. 3, the first electrical connection segment 21 may include a first electrical connection segment 211 and a second electrical connection segment 212 connected to the first electrical connection segment 211. The first electrical connection segment 211 is electrically connected to the first pin terminal 31. The second electrical connection segment 212 is positioned at a side of the first electrical connection segment 211 away from the first pin terminal 31. The second electrical connection segment 212 is electrically connected to the gate line 11. A length of the second electrical connection segment 212 is directly proportional to a width of the second electrical connection segment 212.

It can be understood that the multiple first electrical connection lines 21 are different from each other in length. The greater the length of the first electrical connection line 21, the greater a resistance of the first electrical connection line 21. This results in an impedance mismatch between the first electrical connection lines 21 of different lengths. In the implementations of the disclosure, by setting the width of the second electrical connection segment 212 of the first electrical connection line 21, the length of the second electrical connection segment 212 is directly proportional to the width of the second electrical connection segment 212, thereby ensuring impedance matching between the first electrical connection lines 21 of different lengths.

In one implementation, for any two first electrical connection lines 21, a length of one second electrical connection segment 212 of the two first electrical connection lines 21 is equal to a first length L1, and a length of another second electrical connection segment 212 of the two first electrical connection lines 21 is equal to a second length L2. A width of the second electrical connection segment 212 that has the first length is equal to a first line width W1, and a width of the second electrical connection segment that thas the second length is equal to a second line width W2. In a case where L1>L2, W1 and W2 satisfy: W1>W2, and L1*W2=L2*W1.

As illustrated in FIG. 4, each of the second electrical connection line 22, the third electrical connection line 23, and the fourth electrical connection line 24 may include a first electrical connection segment and a second electrical connection segment. A configuration of each of the second electrical connection segment of the second electrical connection line 22, the second electrical connection segment of the third electrical connection line 23, and the second electrical connection segment of the fourth electrical connection line 24 can refer to the configuration of the second electrical connection segment 212 of the first electrical connection line 21. Specifically, details are not described herein again.

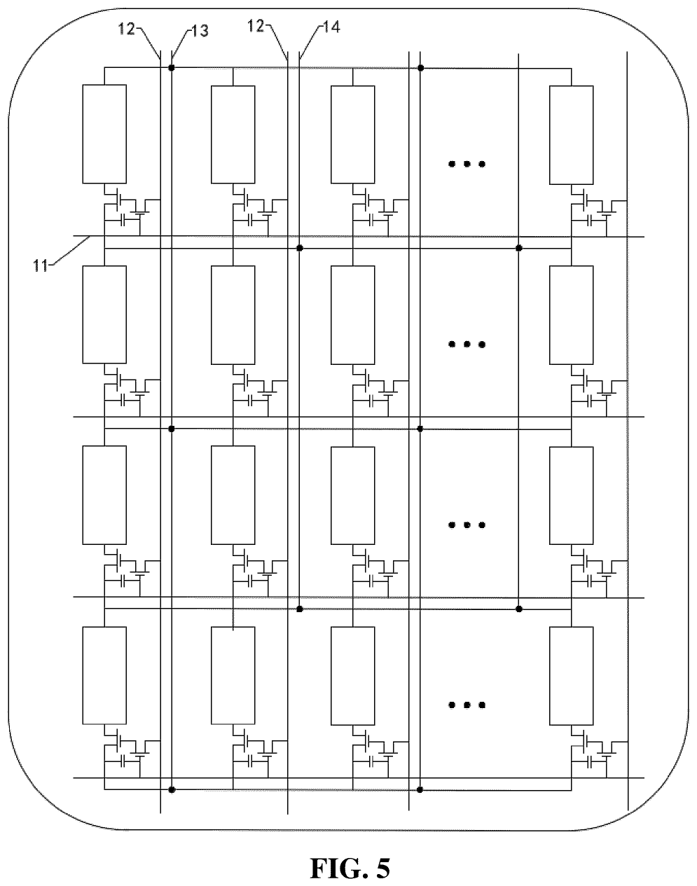

FIG. 5 is a schematic diagram illustrating a drive circuit of the display panel 1 in FIG. 1.

As illustrated in FIG. 5, exemplarily, the gate line 11 may be disposed perpendicular to the first side edge 104a of the display panel 1. The data line 12, the first power line 13, and the second power line 14 may be disposed perpendicular to the second side edge 105a of the display panel 1. The gate line 11 may be disposed perpendicular to the data line 12, the first power line 13, and the second power line 14.

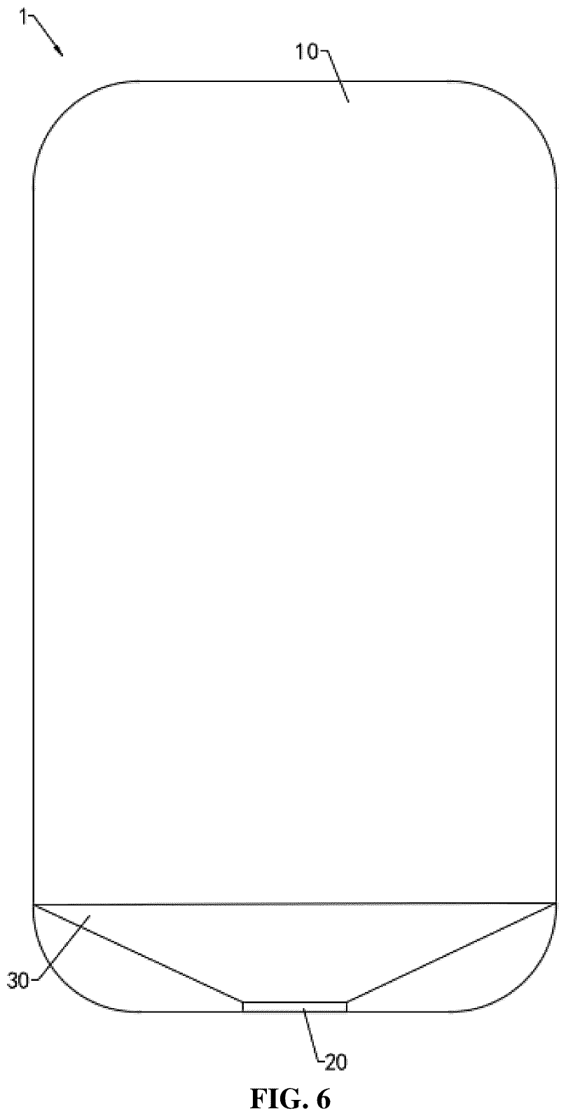

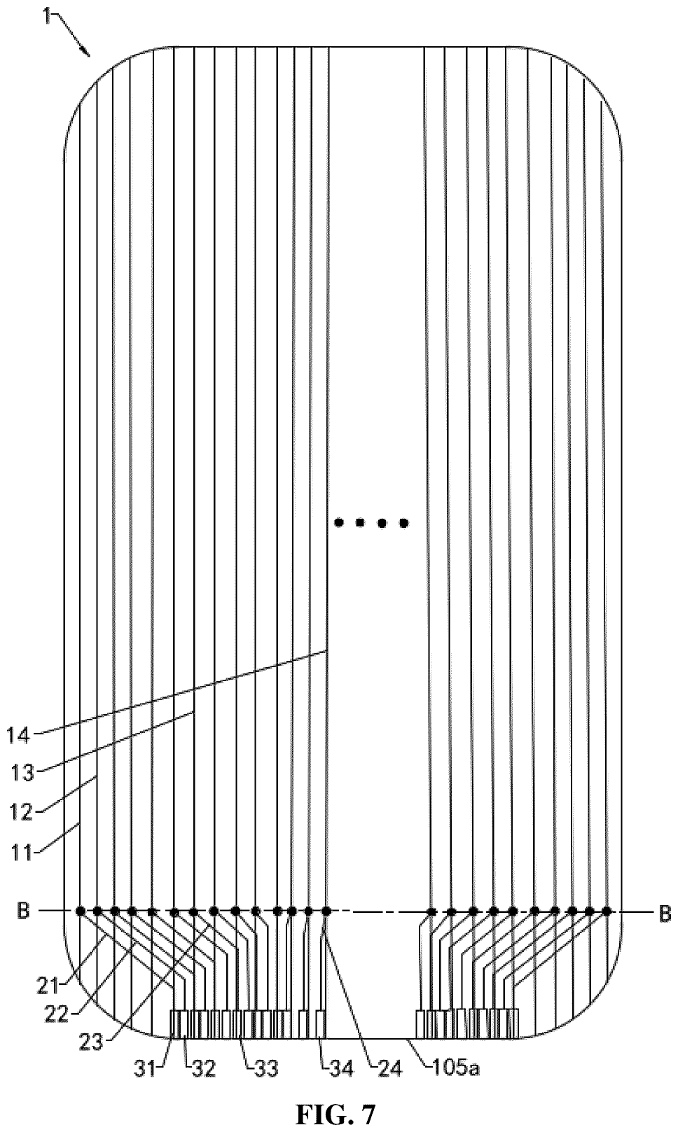

FIG. 6 is a schematic structural diagram of the display panel 1 in FIG. 1 according to an implementation of the disclosure. FIG. 7 is a schematic diagram illustrating part of wirings of the display panel 1 in FIG. 6.

As illustrated in FIGS. 6 and 7, the first pin terminal 31, the second pin terminal 32, the third pin terminal 33, the fourth pin terminal 34, the first electrical connection line 21, the second electrical connection line 22, the third electrical connection line 23, and the fourth electrical connection line 24 are arranged close to the same side of the display panel 1. The first pin terminal 31, the second pin terminal 32, the third pin terminal 33, and the fourth pin terminal 34 are connected to the same side edge of the display panel 1. It should be understood that, both the fan-out region 20 and the binding region 30 of the display panel 1 of the implementations of the disclosure may be arranged close to the second side edge 105a of the display region 10.

Exemplarily, the first pin terminal 31, the second pin terminal 32, the third pin terminal 33, and the fourth pin terminal 34 may be disposed to be connected to the second side edge 105a of the display panel 1. One end of the first electrical connection line 21 extends towards the second side edge 105a of the display panel 1 and is electrically connected to the first pin terminal 31. The second pin terminal 32, the third pin terminal 33, and the fourth pin terminal 34 are arranged close to the second side edge 105a of the display panel 1. One end of the second electrical connection line 22 extends towards the second side edge 105a of the display panel 1 and is electrically connected to the second pin terminal 32. One end of the third electrical connection line 23 extends towards the second side edge 105a of the display panel 1 and is electrically connected to the third pin terminal 33. One end of the fourth electrical connection line 24 extends towards the second side edge 105a of the display panel 1 and is electrically connected to the fourth pin terminal 34.

Exemplarily, the gate line 11, the data line 12, the first power line 13, and the second power line 14 may be arranged parallel to each other. The gate line 11, the data line 12, the first power line 13, and the second power line 14 may all be arranged perpendicular to the second side edge 105a of the display panel 1.

Exemplarily, the gate lines 11 and the data lines 12 are arranged alternately. It can be understood that each gate line 11 and each data line 12 are arranged alternately to form a combination of the gate line 11 and the data line 12.

Exemplarily, the first power line 13 is spaced apart from the second power line 12. Multiple sets of combinations of the gate line 11 and the data line 12 are arranged among the first power lines 13 and the second power lines 14. Specifically, the gate lines 11, the data lines 12, the first power lines 13, and the second power lines 14 may be arranged as follows. Three sets of combinations of the gate line 11 and the data line 12 and one first power line 13 are arranged at intervals in sequence, and another three sets of combinations of the gate line 11 and the data line 12 and one second power line 14 are arranged at intervals in sequence, and this arrangement is repeated.

In this way, the multiple first power supply lines 13 and the multiple second power supply lines 14 can be arranged evenly among the multiple sets of combinations of the gate line 11 and the data line 12. This can ensure that the driving voltages of various regions of the display panel 1 are consistent, thereby avoiding uneven display of the display panel 1.

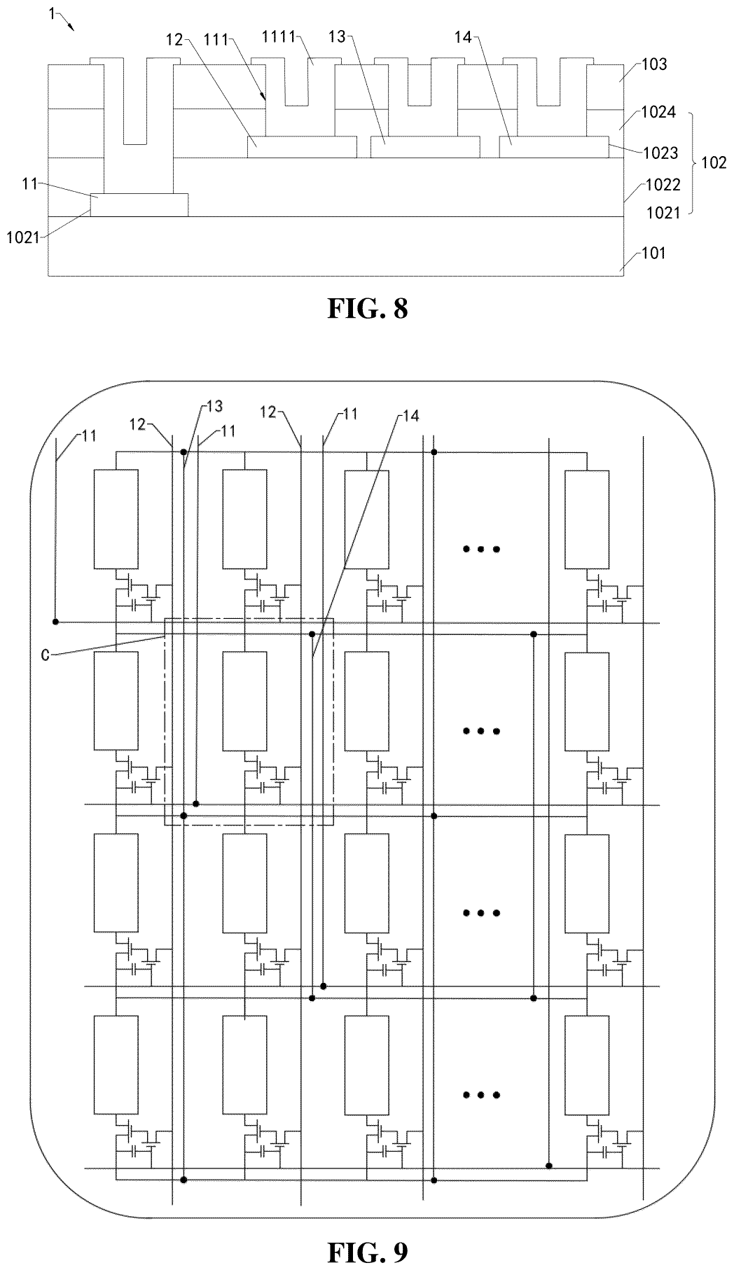

FIG. 8 is a cross-sectional diagram of the display panel 1 in FIG. 7, taken alone line B-B.

As illustrated in FIG. 8, the functional structure layer 102 includes a first metal layer 1021, a second insulation layer 1022, and a second metal layer 1023 stacked sequentially. The first metal layer 1021 may be used for forming the gate line 11. The second metal layer 1023 may be used for forming the data line 12, the first power line 13, and the second power line 14.

Exemplarily, the multiple gate lines 11 are arranged on the first metal layer 1021.

Exemplarily, the multiple data lines 12, the multiple first power supply lines 13, and the multiple second power supply lines 14 are arranged on the second metal layer 1023.

As illustrated in FIG. 8, the display panel 1 defines multiple first through holes 111 extending through the first insulation layer 103. The electrical connection line is electrically connected to the function wire through the first through hole 111.

Exemplarily, a first conductive block 1111 may be disposed in the first through hole 111. Part of the first conductive block 1111 may be received in the first through hole 111, and another part of the first conductive block 1111 may extend out of the first through hole 111. The electrical connection line may be electrically connected to the functional line through the first conductive block 1111.

In an implementation, the first through hole 111 may extend through the first insulation layer 103 and the second insulation layer 1022. The first electrical connection line 21 may be electrically connected to the gate line 11 through the first through hole 111.

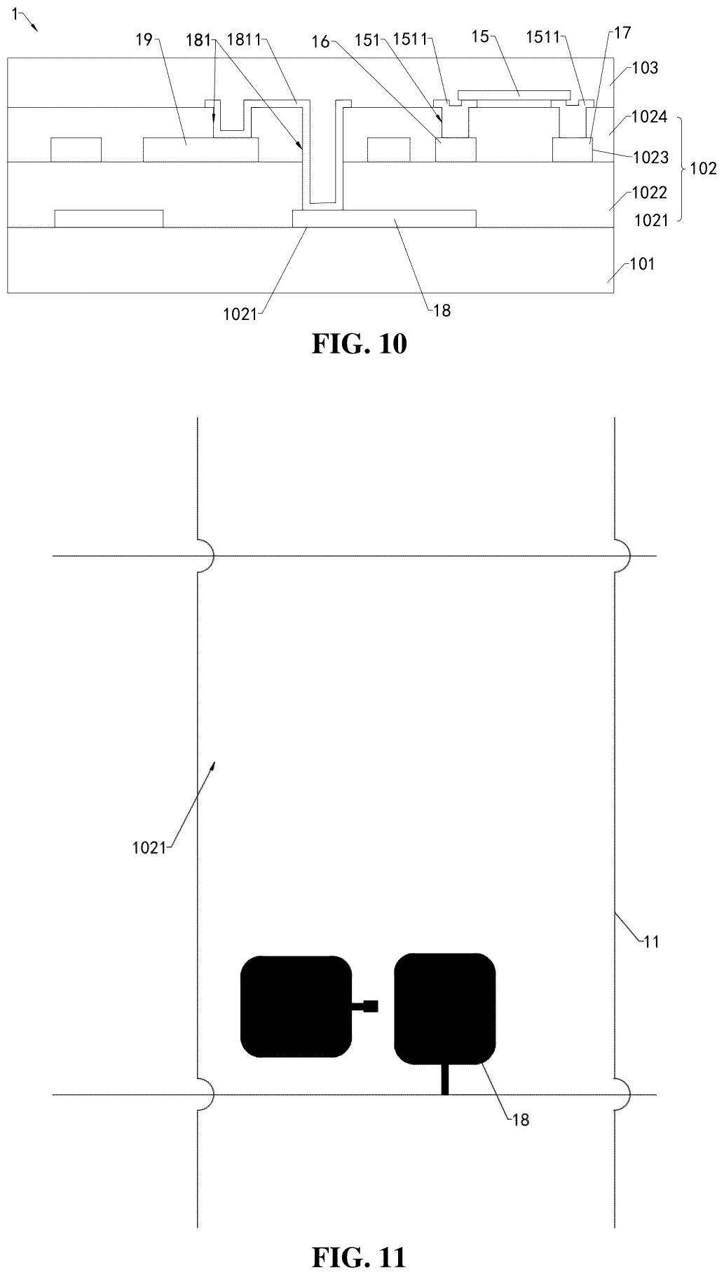

FIG. 9 is a schematic diagram illustrating a drive circuit of the display panel 1 in FIG. 6. FIG. 10 is a partial diagram of stacking structures of the display panel 1 in FIG. 9 at position C.

As illustrated in FIGS. 9 and 10, the display panel 1 further includes a light-emitting element 15. The light-emitting element 15 is designed in a bottom-emission configuration. The light-emitting element 15 is configured to emit light that passes through the substrate 101 and bypasses the binding region 30.

Exemplarily, the light-emitting element 15 is disposed at the film side of the substrate 101. The light-emitting element 15 is positioned between the functional structure layer 102 and the binding region 30.

It can be understood that, the light-emitting element 15 in the implementations of the disclosure is designed in a bottom-emission configuration. That is, the light-emitting element 15 is configured to emit light towards the substrate 101, and the light radiates towards a direction away from the first insulation layer 103. In addition, the light emitted by the light-emitting element 15 will bypass the binding region 30 laminated on the first insulation layer 103, and thus does not affect the performance of the binding region 30.

Exemplarily, the light-emitting element 15 may be a light emitting diode, for example, an organic light emitting diode (OLED), a micro light emitting diode (Micro LED), or the like.

As illustrated in FIGS. 9 and 10, the second metal layer 1023 further includes a first power supply 16 and a second power supply 17. The first power supply 16 is electrically connected to the first power supply line 13. The second power supply 17 is electrically connected to the second power supply line 14.

Exemplarily, the first power supply 16 may have a voltage of VDD. The first power supply line 13 may be a VDD line. The second power supply 17 may have a voltage of VSS. The second power supply line 14 may be a VSS line.

Exemplarily, the display panel 1 further includes a third insulation layer 1024 stacked on the second metal layer 1023. The third insulation layer 1024 is used for protecting the components, preventing harmful impurities from contaminating surfaces of the components, thereby improving stability and reliability of the components.

As illustrated in FIGS. 9 and 10, the first power supply 16 and the second power supply 17 are electrically connected to the light-emitting element 15 to power the light-emitting element 15.

Exemplarily, the display panel 1 may define multiple second through holes 151. The second through holes 151 may extend through the third insulation layer 1024. The first power supply 16 and the second power supply 17 may be electrically connected to the light-emitting element 15 through the second through hole 151.

Exemplarily, a second conductive block 1511 may be disposed in the second through hole 151. The first power supply 16 and the second power supply 17 may be electrically connected to the light-emitting element 15 through the second conductive block 1511. For a configuration of the second conductive block 1511, reference may be made to a configuration of the first conductive block 1111, which is not repeated herein.

As illustrated in FIGS. 9 and 10, the first metal layer 1021 further includes a gate 18 electrically connected to the gate line 11. The display panel 1 further includes a transistor 19, which can be configured to receive a gate signal. The transistor 19 is disposed on the second metal layer 1023. The transistor 19 may be electrically connected to the gate 18 to receive to the gate signal.

Exemplarily, the transistor 19 may be a thin film transistor (TFT).

Exemplarily, the display panel 1 may include multiple third through holes 181. The third through holes 181 may extend through the third insulation layer 1024 and the second insulation layer 1022. The gate 18 may be electrically connected to the transistor 19 through the third through hole 181.

Exemplarily, a third conductive block 1811 may be disposed in the third through hole 181. The gate 18 may be electrically connected to the transistor 19 through the third conductive block 1811. For a configuration of the third conductive block 1811, reference may be made to the configuration of the first conductive block 1111, which is not repeated herein.

The gate 18 in the implementations of the disclosure is electrically connected to the transistor 19. That is, the gate 18 is designed with a gate driver less (GDL) configuration. The gate 18 is directly input with the gate signal by an integrated circuit (IC), and no additional gate driver is required. This enables a conversion of a non-display region originally used for the gate driver at both sides of the display panel 1 into part of the display region 10, thereby achieving a bezel-less design of the display panel 1.

FIG. 11 is a first partial structural diagram of the driver circuit in FIG. 9 at location C. Exemplarily, FIG. 11 illustrates a partial structural diagram of the first metal layer 1021.

As illustrated in FIG. 11, the first metal layer 1021 is formed on the substrate 101. The gate line 11 and the gate 18 of the display panel 1 are formed by the first metal layer 1021. The gate 18 is electrically connected to the gate line 11.

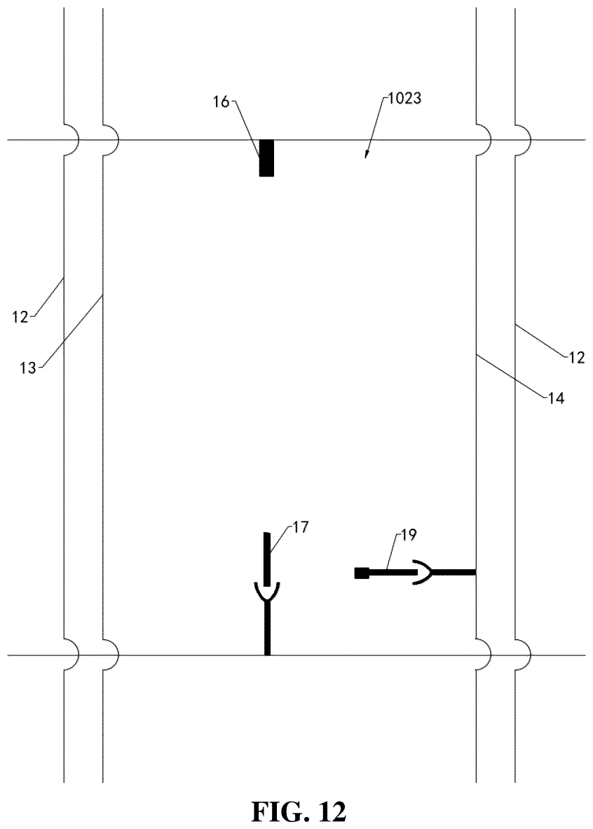

FIG. 12 is a second partial structural diagram of the driver circuit in FIG. 9 at location C. Exemplarily, FIG. 12 illustrates a partial structural diagram of the second metal layer 1023.

As illustrated in FIG. 12, a second insulation layer 1022 and a second metal layer 1023 are sequentially formed on the first metal layer 1021. The data line 12, the first power line 13, the second power line 14, the first power supply 16, the second power supply 17, and the transistor 19 are formed on the second insulation layer 102. The first power supply 16 is electrically connected to the first power line 13. The second power supply 17 is electrically connected to the second power line 14. The transistor 19 is electrically connected to the data line 12.

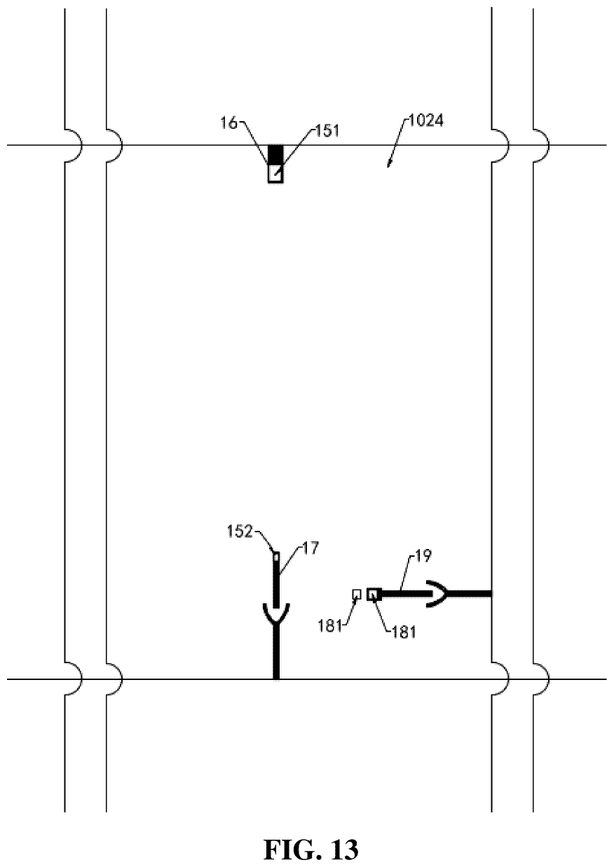

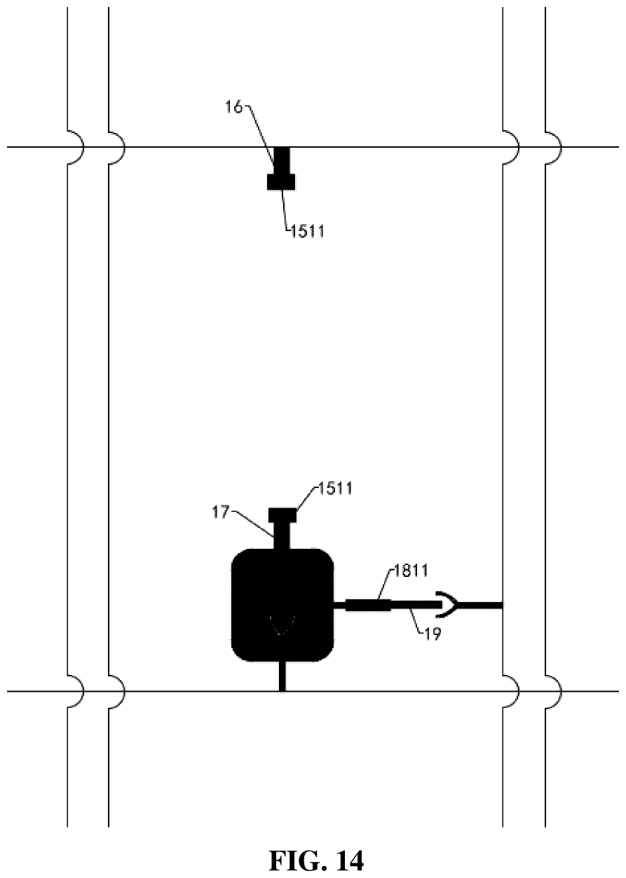

FIG. 13 is a third partial structural diagram of the driver circuit in FIG. 9 at location C. FIG. 14 is a fourth partial structural diagram of the driver circuit in FIG. 9 at location C. Exemplarily, FIG. 13 illustrates a structural diagram part of structures on the third insulation layer 1024. FIG. 14 illustrates a structural diagram of the second conductive block 1511 and the third conductive block 1811.

As illustrated in FIGS. 13 and 14, a third insulation layer 1024 is formed on the second metal layer 1024. A third through hole 181 is formed, by etching, above a position where the first metal layer 1021 is connected to the second metal layer 1023. The third through hole 181 may extend through the second insulation layer 1022 and the third insulation layer 1024, so that part of the first metal layer 1021 and part of the second metal layer 1023 may be exposed.

The third conductive block 1811 is disposed in the third through hole 181 and is electrically connected to the gate 18 on the first metal layer 1021 and the transistor 19 on the second metal layer 1023.

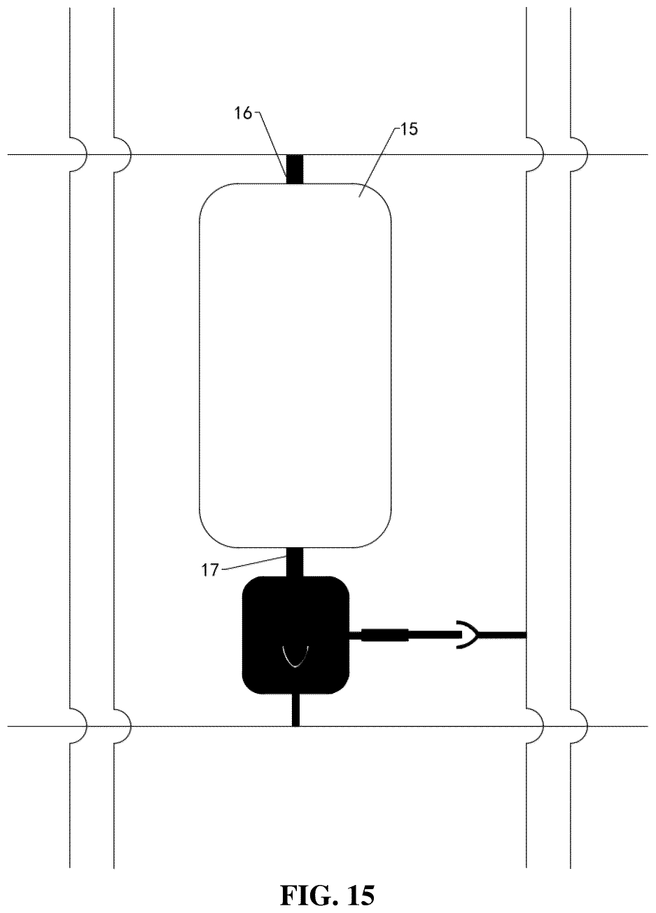

FIG. 15 is a fifth partial structural diagram of the driver circuit in FIG. 9 at location C. Exemplarily, FIG. 15 illustrates a connection between the light-emitting element 15 and the display panel 1.

As illustrated in FIGS. 14 and 15, a second through hole 151 is formed by etching the third insulation layer 1024 that is above the light-emitting element 15. The first power supply 16 and the second power supply 17 are connected to the second through hole 151. The second through hole 151 may extend through the third insulation layer 1024, so that part of the second metal layer 1023 is exposed.

The second conductive block 1511 (i.e., a bonding pad) is formed in the second through hole 151, so that the second conductive block 1511 is electrically connected to the first power supply 16, the second power supply 17, and the light-emitting element 15.

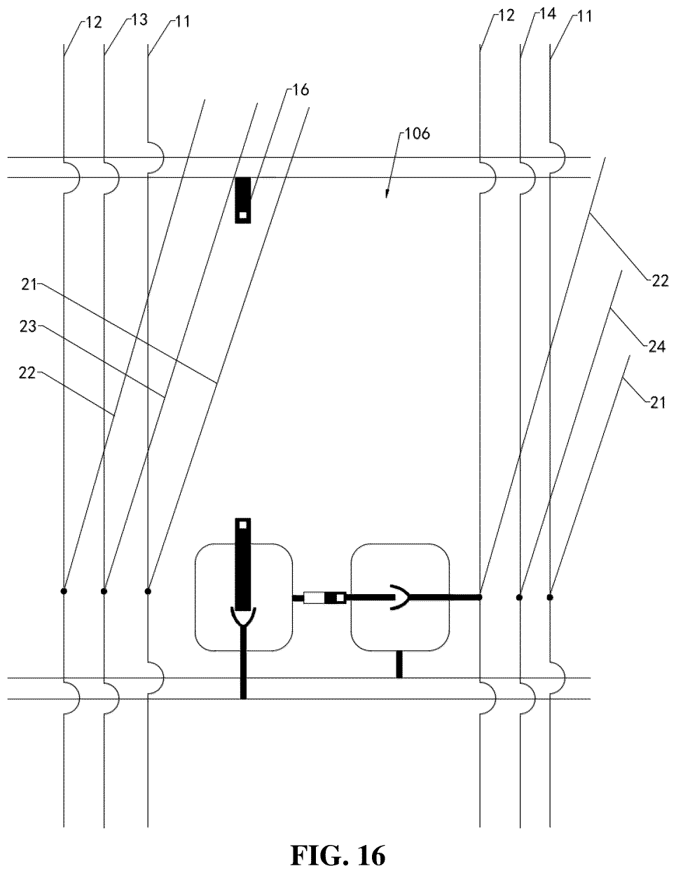

FIG. 16 is a sixth partial structural diagram of the driver circuit in FIG. 9 at location C. Exemplarily, FIG. 16 illustrates part of the structures on the third metal layer 106.

As illustrated in FIG. 16, a first insulation layer 103 and a third metal layer 106 are sequentially formed on the third insulation layer 1024. The electrical connection lines and the pin terminals are formed on the third metal layer 106.

The first through holes 111 are defined at positions above the functional lines to which the electrical connection lines are connected. The first through hole 111 may extend through the first insulation layer 103. Part of the first through holes 111 may extend through the second insulation layer 1022, so that the gate line 11, the data line 12, the first power line 13, and the second power line 14 may be exposed.

The first conductive block 1111 is formed in the first through hole 111. The first conductive block 1111 electrically connects the functional line to a corresponding electrical connection line. That is, the first conductive blocks 1111 may electrically connect the gate line 11, the data line 12, the first power line 13, and the second power line 14 to the first electrical connection line 21, the second electrical connection line 22, the third electrical connection line 23, and the fourth electrical connection line 24, respectively.

In an exemplary implementation, the through holes in the display panel 1 may be defined by at least one of dry etching or wet etching on part of layers.

In exemplary implementations, each of the first metal layer 1021, the second metal layer 1023, and the third metal layer 106 may be made of any one or more of silver (Ag), copper (Cu), aluminum (Al), or molybdenum (Mo), or alloys of the aforementioned metals, such as aluminum-neodymium alloy (AlNd) or molybdenum-niobium alloy (MoNb). Each of the first metal layer 1021, the second metal layer 1023, and the third metal layer 106 may be a single-layer structure, or a multi-layer composite structure (for example, a composite structure of a Mo layer, a Cu layer, and a Mo layer).

A material of each of the first conductive block 1111, the second conductive block 1511, and the third conductive block 1811 can reference the material of the first metal layer 1021. Each of the first conductive block 1111, the second conductive block 1511, and the third conductive block 1811 may also be made of indium tin oxide (ITO) and indium zinc oxide (IZO), but are not limited thereto.

Each of the first insulation layer 103 and the second insulation layer 1022 may be made of any one or more of a polyfluoroalkoxy (PFA), a silicon oxide (SiO_{X}), a silicon nitride (SiN_{X}), and a silicon oxynitride (SiON). Each of the first insulation layer 103 and the second insulation layer 1022 may be a single layer, a multilayer, or a composite layer. These materials are provided as examples and are not meant to impose specific limitations. The second insulation layer 1022 may serve as a gate insulation (GI) layer. The third insulation layer 1024 may serve as a passivation (PV) layer.

While the disclosure has been described in detail above with reference to the exemplary embodiments, the scope of the disclosure is not limited thereto. As will occur to those skilled in the art, the disclosure is susceptible to various modifications and changes without departing from the scope of the disclosure. Therefore, the scope of the disclosure should be determined by the scope of the claims.

What is claimed is:

1. A display panel, comprising a display region, a fan-out region, and a binding region, the fan-out region and the binding region being stacked on the display region, and the binding region being co-planar with the fan-out region, wherein
the display region comprises a substrate, a functional structure layer, and a first insulation layer stacked sequentially, wherein the fan-out region and the binding region are stacked on the first insulation layer;
the functional structure layer comprises a plurality of functional lines, the fan-out region comprises a plurality of electrical connection lines, and the binding region comprises a plurality of pin terminals; and
the plurality of electrical connection lines electrically connect the plurality of functional lines to the plurality of pin terminals in one-to-one correspondence.

2. The display panel of claim 1, wherein
the plurality of functional lines comprise a plurality of gate lines, a plurality of data lines, a plurality of first power lines, and a plurality of second power lines;
the plurality of electrical connection lines comprise first electrical connection lines, second electrical connection lines, third electrical connection lines, and fourth electrical connection lines;
the plurality of pin terminals comprise first pin terminals, second pin terminals, third pin terminals, and fourth pin terminals; and
each of the first electrical connection lines electrically connects one of the plurality of gate lines to one of the first pin terminals; each of the second electrical connection lines electrically connects one of the plurality of data lines to one of the second pin terminals; each of the third electrical connection lines electrically connects one of the plurality of first power lines to one of the third pin terminals; and each of the fourth electrical connection lines electrically connects one of the plurality of second power lines to one of the fourth pin terminals.

3. The display panel of claim 2, comprising a first side edge, a third side edge opposite the first side edge, a second side edge, and a fourth side edge opposite the second side edge, the first side edge and the third side edge being connected between the second side edge and the fourth side edge; wherein
the first pin terminals and the first electrical connection lines are closer to the first side edge than the third side edge; and
the second pin terminals, the third pin terminals, the fourth pin terminals, the second electrical connection lines, the third electrical connection lines, and the fourth electrical connection lines are closer to the second side edge than the fourth side edge.

4. The display panel of claim 3, wherein the first pin terminals are connected to the first side edge, and the second pin terminals, the third pin terminals, and the fourth pin terminals are connected to the second side edge.

5. The display panel of claim 2, comprising a first side edge, a third side edge opposite the first side edge, a second side edge, and a fourth side edge opposite the second side edge, the first side edge and the third side edge being connected between the second side edge and the fourth side edge; wherein
the first pin terminals, the second pin terminals, the third pin terminals, the fourth pin terminals, the first electrical connection lines, the second electrical connection lines, the third electrical connection lines, and the fourth electrical connection lines are close to one of the first side edge, the second side edge, the third side edge, and the fourth side edge.

6. The display panel of claim 5, wherein the first pin terminals, the second pin terminals, the third pin terminals, and the fourth pin terminals are connected to one of the first side edge, the second side edge, the third side edge, and the fourth side edge.

7. The display panel of claim 2, defining a plurality of through holes extending through the first insulation layer, each of the plurality of electrical connection lines being electrically connected to one of the plurality of functional lines through one of the plurality of through holes.

8. The display panel of claim 7, wherein the functional structural layer comprises a first metal layer, a second insulation layer, and a second metal layer stacked sequentially, the plurality of gate lines are arranged on the first metal layer, and the plurality of data lines, the plurality of first power lines, and the plurality of second power lines are arranged on the second metal layer;
part of the plurality of through hole extends through the second insulation layer to enable each of the first electrical connection lines to be electrically connected to one of the plurality of gate lines.

9. The display panel of claim 1, further comprising a light-emitting element configured to emit light that passes through the substrate and bypasses the binding region.

10. A display device, comprising a housing and a display panel, wherein
the display panel comprises a display region, a fan-out region, and a binding region, the fan-out region and the binding region being stacked on the display region, and the binding region being co-planar with the fan-out region;
the display region comprises a substrate, a functional structure layer, and a first insulation layer stacked sequentially, wherein the fan-out region and the binding region are stacked on the first insulation layer;
the functional structure layer comprises a plurality of functional lines, the fan-out region comprises a plurality of electrical connection lines, and the binding region comprises a plurality of pin terminals; and
the plurality of electrical connection lines electrically connect the plurality of functional lines to the plurality of pin terminals in one-to-one correspondence.

11. The display device of claim 10, wherein
the plurality of functional lines comprise a plurality of gate lines, a plurality of data lines, a plurality of first power lines, and a plurality of second power lines;
the plurality of electrical connection lines comprise first electrical connection lines, second electrical connection lines, third electrical connection lines, and fourth electrical connection lines;
the plurality of pin terminals comprise first pin terminals, second pin terminals, third pin terminals, and fourth pin terminals; and
each of the first electrical connection lines electrically connects one of the plurality of gate lines to one of the first pin terminals; each of the second electrical connection lines electrically connects one of the plurality of data lines to one of the second pin terminals; each of the third electrical connection lines electrically connects one of the plurality of first power lines to one of the third pin terminals; and each of the fourth electrical connection lines electrically connects one of the plurality of second power lines to one of the fourth pin terminals.

12. The display device of claim 11, comprising a first side edge, a third side edge opposite the first side edge, a second side edge, and a fourth side edge opposite the second side edge, the first side edge and the third side edge being connected between the second side edge and the fourth side edge; wherein
the first pin terminals and the first electrical connection lines are closer to the first side edge than the third side edge; and
the second pin terminals, the third pin terminals, the fourth pin terminals, the second electrical connection lines, the third electrical connection lines, and the fourth electrical connection lines are closer to the second side edge than the fourth side edge.

13. The display device of claim 12, wherein the first pin terminals are connected to the first side edge, and the second pin terminals, the third pin terminals, and the fourth pin terminals are connected to the second side edge.

14. The display device of claim 11, comprising a first side edge, a third side edge opposite the first side edge, a second side edge, and a fourth side edge opposite the second side edge, the first side edge and the third side edge being connected between the second side edge and the fourth side edge; wherein
the first pin terminals, the second pin terminals, the third pin terminals, the fourth pin terminals, the first electrical connection lines, the second electrical connection lines, the third electrical connection lines, and the fourth electrical connection lines are close to one of the first side edge, the second side edge, the third side edge, and the fourth side edge.

15. The display device of claim 14, wherein the first pin terminals, the second pin terminals, the third pin terminals, and the fourth pin terminals are connected to one of the first side edge, the second side edge, the third side edge, and the fourth side edge.

16. The display device of claim 11, defining a plurality of through holes extending through the first insulation layer, each of the plurality of electrical connection lines being electrically connected to one of the plurality of functional lines through one of the plurality of through holes.

17. The display device of claim 16, wherein
the functional structural layer comprises a first metal layer, a second insulation layer, and a second metal layer stacked sequentially, the plurality of gate lines are arranged on the first metal layer, and the plurality of data lines, the plurality of first power lines, and the plurality of second power lines are arranged on the second metal layer;
part of the plurality of through hole extends through the second insulation layer to enable each of the first electrical connection lines to be electrically connected to one of the plurality of gate lines.

18. The display device of claim 10, further comprising a light-emitting element configured to emit light that passes through the substrate and bypasses the binding region.
